(19) United States
(12) Patent Application Publication
(10) Pub. No.: US 2022/0209082 A1
(43) Pub. Date: Jun. 30, 2022

(54) METHOD FOR TRANSFERRING CHIPS AND METHOD FOR MANUFACTURING LED DISPLAY

(71) Applicant: ASTI GLOBAL INC., TAIWAN, Taichung City (TW)

(72) Inventors: CHIEN-SHOU LIAO, Taichung City (TW); YU-MIN HUANG, Taichung City (TW); CHIH-CHENG WANG, Taichung City (TW); SHENG-CHE HUANG, Taichung City (TW)

(21) Appl. No.: 17/516,717

(22) Filed: Nov. 2, 2021

(30) Foreign Application Priority Data
Dec. 31, 2020 (TW) 109147026

(51) Int. Cl. H01L 33/62; H01L 25/075; H01L 33/00

(52) U.S. Cl. CPC H01L 33/62; H01L 2933/0066; H01L 33/005; H01L 25/0753

(57) ABSTRACT

A method for transferring chips and a method for manufacturing an LED display are introduced. The method for manufacturing the LED display includes the method for transferring chips. The method for transferring chips includes providing a carrier substrate on which multiple LED chips are carried; providing a target substrate on which wires capable of forming circuits with the LED chips are disposed; transferring the LED chips carried on the carrier substrate onto the wires; galvanizing the wires to trigger at least partial of the LED chips to generate light by the circuits formed; checking the LED chips forming the circuit and fixing the LED chips generating light on the wire; and removing LED chips which fail to generate light.

### CROSS-REFERENCE TO RELATED APPLICATION

This non-provisional application claims priority under 35 U.S.C. § 119(a) on Patent Application No(s). 109147026 filed in Taiwan, R.O.C. on Dec. 31, 2020, the entire contents of which are hereby incorporated by reference.

### BACKGROUND OF THE INVENTION

### 1. Field of the Invention

The present disclosure relates to a method for transferring chips and a method for manufacturing an LED display, and in particular to a method for transferring chips and a method for manufacturing an LED display capable of detecting whether the chips are aligned normally before die bonding.

### 2. Description of the Related Art

In general, to neatly weld a large number of light-emitting diode (LED) chips to a circuit substrate, the process usually involves the following steps: alignment, lamination, welding, and power-on lighting. In the order of these steps, a large number of chips can be transferred.

In the transferring process of a large number of chips, it is inevitable that a small number of light-emitting diode chips cause a failure to be lit due to the misalignment, however, because of the limitation of the process of existing technology and equipment defects, technicians are unable to find and improve timely the position misalignment of a small number of light-emitting diode chips. When a small number of light-emitting diode chips were found to be unable to light up, the small number of light-emitting diode chips had welded on the circuit substrate, requiring additional time, money, and labor costs to remediate.

Therefore, it has become one of the important issues that the industry wants to solve how to improve the structure design to increase the success rate of light-emitting diode chips in the process of mass transferring, in order to overcome the above defects.

### BRIEF SUMMARY OF THE INVENTION

The technical problem to be solved by the disclosure is to provide a method for transferring chips regarding the deficiency of the state of the art.

To solve the above technical problem, the present disclosure provides a method for transferring chips, which includes: providing a carrier substrate on which multiple light-emitting diode chips are carried; providing a target substrate on which wires capable of forming circuits with the light-emitting diode chips are disposed; transferring the light-emitting diode chips carried on the carrier substrate onto the wires; galvanizing the wire to trigger at least partial of the light-emitting diode chips to generate light by the circuits formed; checking the light-emitting diode chips forming the circuits and fixing the at least partial of the light-emitting diode chips generating light on the wires; and removing light-emitting diode chips which fail to generate light.

To solve the above technical problem, the disclosure provides a method for manufacturing an LED display, which includes the method for transferring chips.

One of the beneficial effects of the disclosure is that the method for transferring chips and the method for manufacturing an LED display provided by the disclosure can improve the yield of a large number of light-emitting diode chips in the transferring process by the technical solutions of “galvanizing the wires to trigger at least partial of the light-emitting diode chips to generate light by the circuits formed” and “fixing the at least partial of the light-emitting diode chips generating light on the substrate”.

In order to further understand the characteristics and technical contents of the present disclosure, please refer to the following detailed description and drawings of the present disclosure, however, the drawings provided are only used to provide reference and description, not to limit the present disclosure.

### BRIEF DESCRIPTION OF THE DRAWINGS

FIG. 1 is a schematic view 1 of a method for transferring chips according to a first embodiment of the present disclosure.

FIG. 2 is a schematic view 2 of a method for transferring chips according to a first embodiment of the present disclosure.

FIG. 3 is a schematic view 3 of a method for transferring chips according to a first embodiment of the present disclosure.

FIG. 4 is a schematic view 4 of a method for transferring chips according to a first embodiment of the present disclosure.

FIG. 5 is a schematic view 1 of a method for transferring chips according to a second embodiment of the present disclosure.

FIG. 6 is a schematic view 2 of a method for transferring chips according to a second embodiment of the present disclosure.

FIG. 7 is a schematic view 3 of a method for transferring chips according to a second embodiment of the present disclosure.

FIG. 8 is a schematic view 4 of a method for transferring chips according to a second embodiment of the present disclosure.

FIG. 9 is a schematic view of steps S1 to S6 of the method for transferring chips of the present disclosure.

### DETAILED DESCRIPTION OF THE INVENTION

The following are specific embodiments to illustrate the implementation of “a method for transferring chips and a method for manufacturing an LED display” disclosed by the present disclosure. One skilled in the art can understand the advantages and effects of this present disclosure by the contents described in the specification. It should be noted that various possible modifications and alterations to the details of the specification could be carried out by implementing or applying other different embodiments based on different views and applications without departing from the spirit of the present disclosure. In addition, the drawings of the present disclosure are only a simple and schematic indication, not be drawn according to the actual size, declared in advance herein. The related technical contents of the disclosure will be described in detail by the embodiments. However, the disclosed contents should not be considered to limit the scope of the disclosure.

It should be understood that while terms such as “first,” “second,” and “third” may be used to describe elements in the specification, these elements should not be limited to these terms. These terms are primarily used to distinguish between one element and another. In addition, the term “or” used in the specification should encompass any one or multiple combinations of the listing items associated, relying on the actual situation.

### The First Embodiment

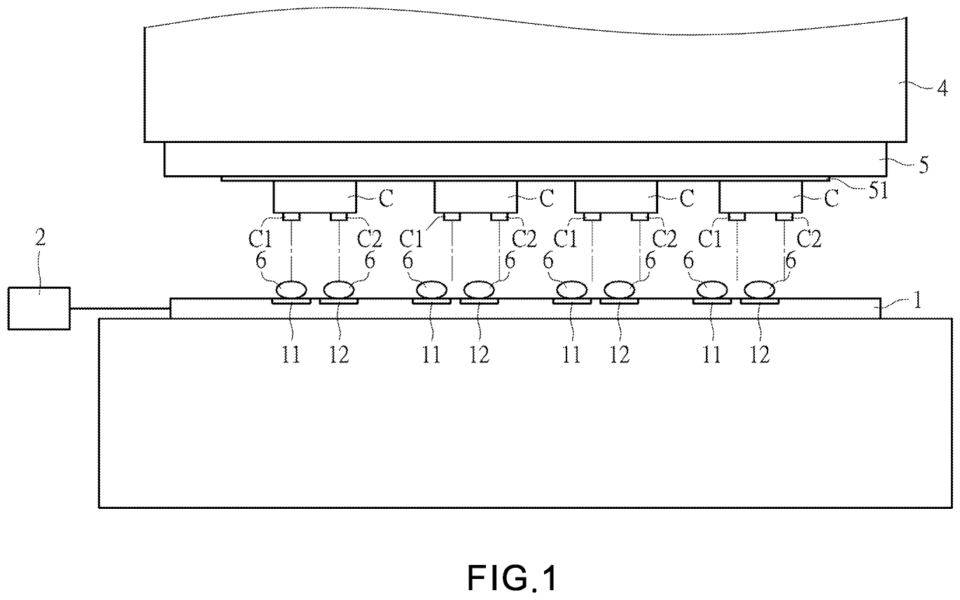

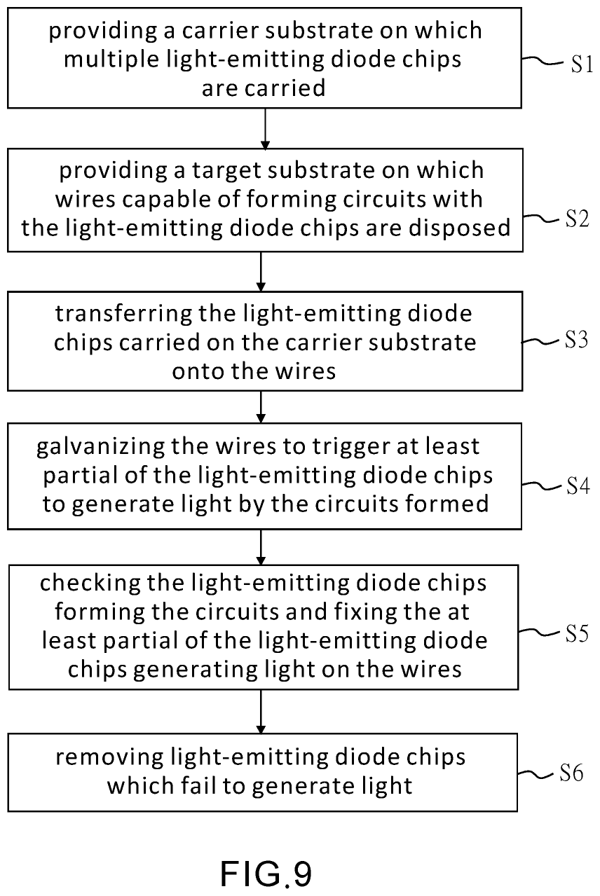

Referring to FIGS. 1 to 4, FIGS. 1 to 4 are schematic views respectively showing each stage of the process of a method for transferring chips according to the first embodiment of the present disclosure. The steps of the method for transferring chips provided by the disclosure can be first referred to FIG. 9, which mainly include:

Step S1: providing a carrier substrate 5 on which multiple light-emitting diode chips C are carried;

Step S2: providing a target substrate 1 on which wires capable of forming circuits with the light-emitting diode chips C are disposed;

Step S3: transferring the light-emitting diode chips C carried on the carrier substrate 5 onto the wires;

Step S4: galvanizing the wires to trigger at least partial of the light-emitting diode chips C to generate light by the circuits formed;

Step S5: checking the light-emitting diode chips C forming the circuits and fixing the at least partial of the light-emitting diode chips C generating light on the wires; and

Step S6: removing light-emitting diode chips C which fail to generate light.

The method for transferring chips provided by the disclosure is mainly realized by a chip transferring system. The chip transferring system includes a target substrate 1, a power supply module 2, a die bonding module 3, a chip transferring module 4 and a carrier substrate 5. The target substrate 1 is placed on a carrier table, the surface of the target substrate 1 has multiple conductive pad components, each conductive pad component includes two conductive pads 11, 12. Alternatively, wires capable of forming circuits with light-emitting diode chips are disposed. The power supply module 2 is electrically connected to the target substrate 1. The die bonding module 3 and the chip transferring module 4 are set above the target substrate 1, in the embodiment, the chip transferring module 4 is a carrying structure, which is used to carry and drive the carrier substrate 5, a surface of the carrier substrate 5 is connected to the chip transferring module 4, the other surface of the carrier substrate has an adhesive layer 51.

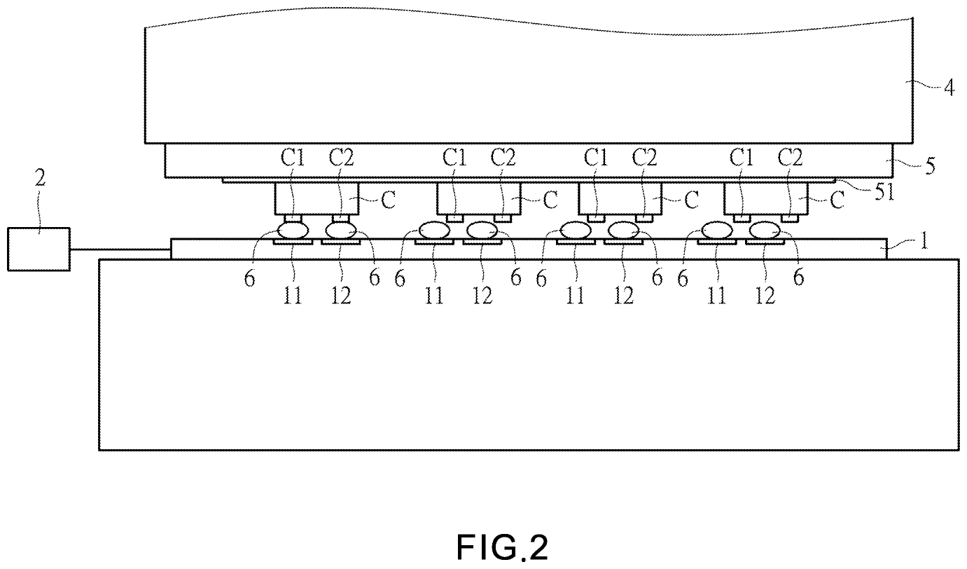

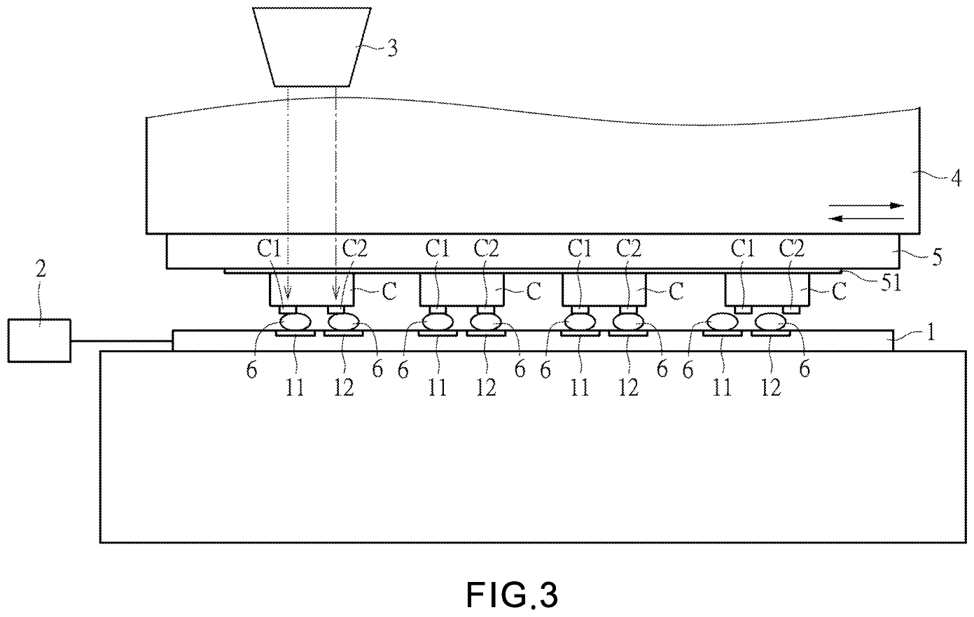

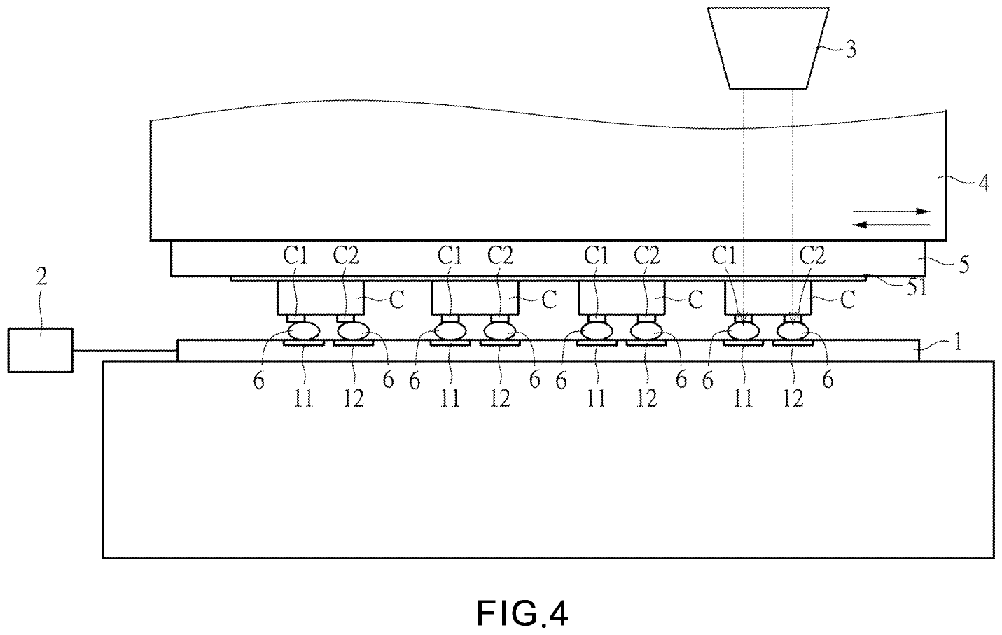

Specifically, as shown in FIG. 1 and FIG. 2, multiple light-emitting diode chips C are glued to the adhesive layer 51 of the carrier substrate 5 before transferring to the target substrate 1. The disclosure is not limited by whether the light-emitting diode chips C have been packaged. In other words, the light-emitting diode chip C can be an unpackaged LED chip (bare die) or a packaged LED chip (forming an LED chip package structure). Next, the light-emitting diode chips C are transferred onto the target substrate 1 at the same time via the chip transferring module 4 (carrying structure). The power supply module 2 provides power to the light-emitting diode chips C, resulting in the light-emitting diode chips C to generate light. However, in the transferring process of a large number of chips, it is inevitable that a small number of the light-emitting diode chips C cause a failure to generate light due to the misalignment, as shown in the right three light-emitting diode chips C of FIG. 2. At this time, the three light-emitting diode chips C are driven to move horizontally through a small range of shaking the chip transferring module 4, so that two of the three light-emitting diode chips C generate light, only the far right light-emitting diode chip C (as shown in FIG. 3) still fails to generate light because of the misalignment. Therefore, in some embodiments, the target substrate 1 can be shaked in order to result in displacements of at least partial of the light-emitting diode chips C thereon to generate light. Next, as shown in FIGS. 3 and 4, the die bonding module 3 fixes the multiple light-emitting diode chips C generating light on the target substrate 1, the die bonding module 3 may be a laser generating equipment used to generate laser light. After that, the chip transferring module 4 removes the far right light-emitting diode chip C that fails to generate light from the target substrate 1, and the chip transferring module 4 then fills a new light-emitting diode chip C into the vacant position created by removing the light-emitting diode chip C that fails to generate light.

Further, after the multiple light-emitting diode chips C that generate light are fixed to the target substrate 1, the multiple light-emitting diode chips C that generate light are disengaged from the adhesion of the adhesive layer 51 of the carrier substrate 5 by the movement of the chip transferring module 4 (carrying structure). The light-emitting diode chip C has two conductive contacts C1, C2, the two conductive contacts C1 and C2 are electrically connected to two conductive pads 11 and 12 of the target substrate 1 respectively by two conductors 6, and the conductors 6 are cured by the irradiation of the laser light generated by the die bonding module 3. For example, two conductors 6 may be two tin balls placed on the conductive pads 11, 12, but the present disclosure is not limited to herein. In other embodiments, two conductors 6 may also be tin layers respectively coated on the two conductive contacts C1 and C2.

It is worth mentioning that when the light-emitting diode chip C is replaced by a non-luminescent electronic chip (e.g., resistance, capacitor), the method for transferring chip provided by the present disclosure includes: first, transferring multiple chips onto a target substrate 1; next, respectively providing multiple feed signals to the chips; then, moving the chips so that at least partial of the chips respectively generate a feedback signal (i.e., the return signal generated by the feed signal passing through the corresponding chip); next, fixing the chips that generate the feedback signals on the target substrate 1; then, removing the chips that fail to generate feedback signals from the target substrate 1; finally, filling preparative chips into vacant positions created by removing the chips that fail to generate feedback signals.

### The Second Embodiment

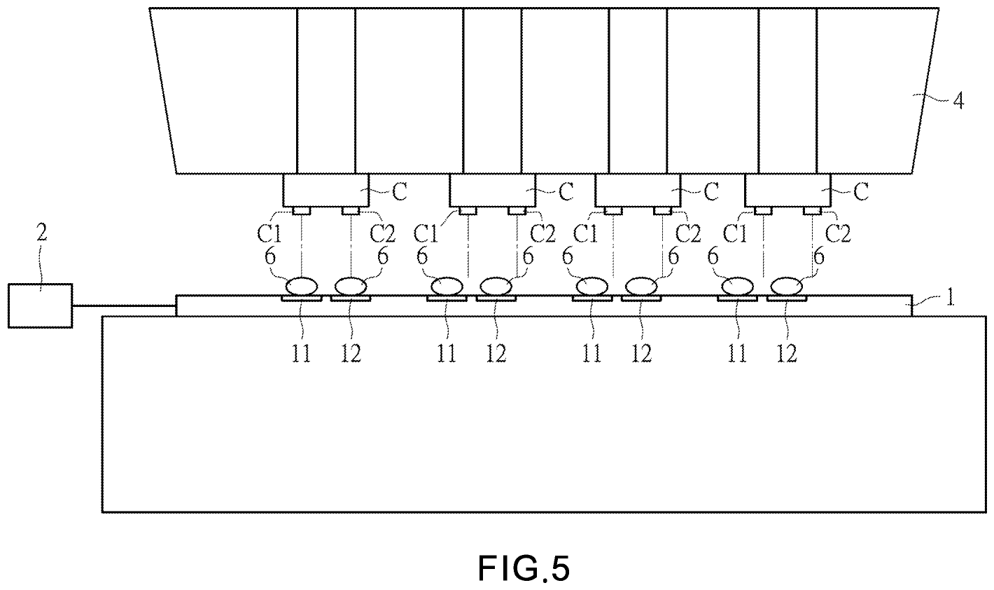

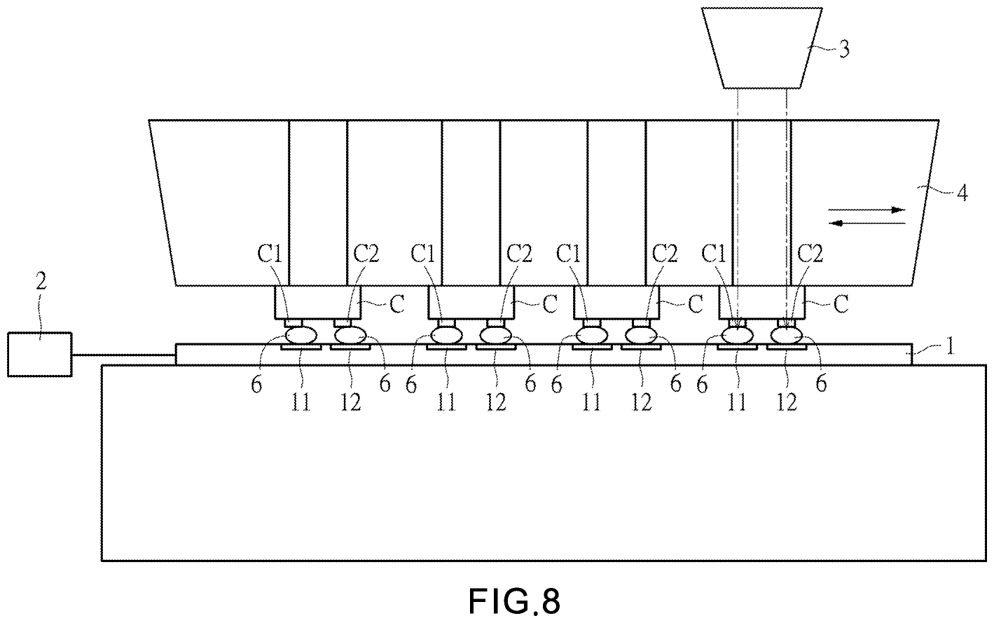

Referring to FIGS. 5 to 8, FIGS. 5 to 8 are schematic views respectively showing each stage of the process of a method for transferring chips according to the second embodiment of the present disclosure.

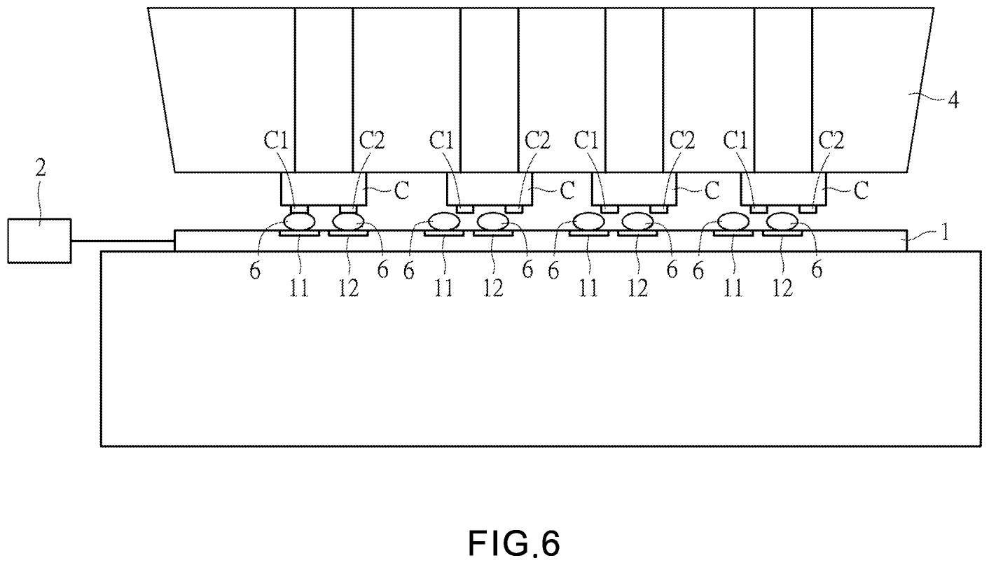

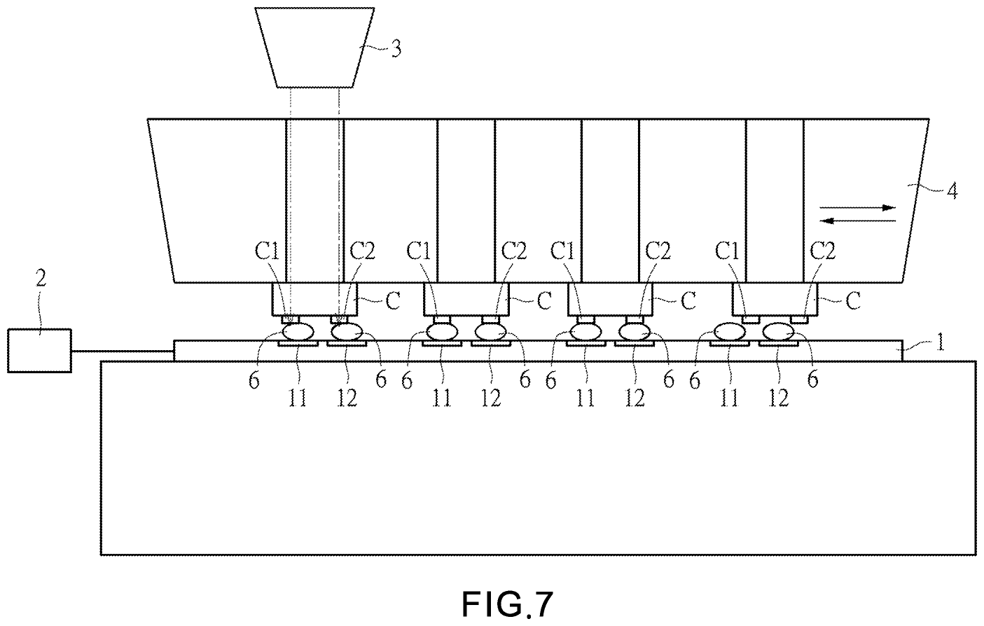

Each process stage in the second embodiment is basically the same as that of the first embodiment. The chip transferring system of the second embodiment includes a target substrate 1, a power supply module 2, a die bonding module 3, a chip transferring module 4 and a carrier substrate 5, the main difference between the chip transferring system of the second embodiment and the chip transferring system of the first embodiment is that the chip transferring module 4 used in the second embodiment is an adsorption structure for adsorbing and driving light-emitting diode chips C. The multiple light-emitting diode chips C are adsorbed by the chip transferring module 4 (absorption structure) before transferring to the target substrate 1. That is, when the chip transferring module 4 is an adsorption structure, it is directly able to adsorb and move multiple light-emitting diode chips C without the carrier substrate 5. The multiple light-emitting diode chips C are transferred onto the target substrate 1 at the same time through the chip transferring module 4 (absorption structure), and two conductive contacts C1, C2 of each light-emitting diode chip C are electrically connected to two conductive pads 11, 12 of the target substrate 1 respectively through two conductors 6 (which may be tin balls or tin layers). The power supply module 2 provides power to multiple light-emitting diode chips C, resulting in multiple light-emitting diode chips C to generate light. However, in the transferring process of a large number of chips, it is inevitable that a small number of light-emitting diode chips C cause a failure to generate light due to the misalignment, as shown in the right three light-emitting diode chips C of FIG. 6. At this time, the three light-emitting diode chips C are driven to move horizontally through a small range of shaking the chip transferring module 4, so as to cause two of the three light-emitting diode chips C to have displacements and generate light, and only the far right light-emitting diode chip C (as shown in FIG. 7) still fails to generate light because of the misalignment.

Next, after the light-emitting diode chips C generating light are fixed on the target substrate 1 through the laser light generated by the die bonding module 3 irradiating two conductors 6, the light-emitting diode chips C generating light are disengaged from the adsorption of the chip transferring module 4 (absorption structure) through a vacuum relief. After that, the chip transferring module 4 removes the far right light-emitting diode chip C that fails to generate light from the target substrate 1, and the chip transferring module 4 then fills a preparative light-emitting diode chip C into the vacant position created by removing the light-emitting diode chip C that fails to generate light.

### The Third Embodiment

The disclosure provides a method for manufacturing LED displays, which includes the method for transferring chips as described above, and the method includes:

Step S1: providing a carrier substrate 5 on which multiple light-emitting diode chips C are carried;

Step S2: providing a target substrate 1 on which wires capable of forming circuits with the light-emitting diode chips C are disposed;

Step S3: transferring the light-emitting diode chips C carried on the carrier substrate 5 onto the wires;

Step S4: galvanizing the wires to trigger at least partial of the light-emitting diode chips C to generate light by the circuits formed;

Step S5: checking the light-emitting diode chips C forming the circuits and fixing the at least partial of the light-emitting diode chips C generating light on the wires; and

Step S6: removing light-emitting diode chips C which fail to generate light.

### The Beneficial Effect of the Embodiments

Another beneficial effect of the disclosure is that the method for transferring chips and the method for manufacturing an LED display provided by the disclosure can improve the yield of a large number of light-emitting diode chips C in the transferring process by the technical solutions of “galvanizing the wires to trigger at least partial of the light-emitting diode chips to generate light by the circuits formed” and “fixing the at least partial of the light-emitting diode chips C generating light on the target substrate 1”.

Furthermore, because the light-emitting diode chips C may not be able to make the conductive contacts C1, C2 of the light-emitting diode chips C accurately align and contact the conductors 6 on the two conductive pads 11, 12 of the target substrate 1 (contacting is incomplete or not even contacted), the conductive contacts C1, C2 and the conductors 6 on the two conductive pads 11, 12 cannot be electrically connected, resulting in no light or the light-emitting power significantly reduced (i.e., the light emitted is quite weak). Therefore, when the light-emitting diode chips 20 have not been welded and fixed on the target substrate 1, the method for transferring chips provided by the disclosure can timely find the misaligned light-emitting diode chips 20 and readjust the contact between the misaligned light-emitting diode chips 20 and the conductors 6 on the two conductive pads 11, 12 of the target substrate 1, so that they can be electrically connected through the horizontal movement of the chip transferring module 4. Compared with the state of the art, the method for transferring chips provided by the present disclosure does not require additional time, money and labor costs, and is a very practical improvement.

The above description is merely preferable embodiments of the disclosure, and it should not be considered to limit the scope of the disclosure. It should be noted that all changes and substitutions which come within the meaning and range of equivalency of the embodiments are intended to be embraced in the scope of the disclosure.

What is claimed is:

1. A method for transferring chips, comprising:
providing a carrier substrate on which multiple light-emitting diode chips are carried;
providing a target substrate on which wires capable of forming circuits with the light-emitting diode chips are disposed;
transferring the light-emitting diode chips carried on the carrier substrate onto the wires;
galvanizing the wires to trigger at least partial of the light-emitting diode chips to generate light by the circuits formed;
checking the light-emitting diode chips forming the circuits and fixing the at least partial of the light-emitting diode chips generating light on the wires; and
removing light-emitting diode chips which fail to generate light.

2. The method for transferring chips according to claim 1, further comprising:
shaking the target substrate to result in displacements of the at least of the light-emitting diode chips on the wires.

3. The method for transferring chips according to claim 2, wherein the step of shaking is carried out before galvanizing the wire or at galvanizing the wire.

4. The method for transferring chips according to claim 1, wherein at least one vacant position is available after removing light-emitting diode chips which fail to generate light, and the method for transferring chips further comprises:
providing at least one preparative light-emitting diode chip; and
placing the at least one preparative light-emitting diode chip into the vacant position, and fixing the at least one preparative light-emitting diode chip on the wire.

5. A method for manufacturing an LED display, comprising using the method for transferring chips according to claim 1, to transfer the light-emitting diode chips onto the target substrate.

6. The method for manufacturing an LED display according to claim 5, wherein the method for transferring chips further comprises:
shaking the target substrate to result in displacements of the at least partial of the light-emitting diode chips on the wires.

7. The method for manufacturing an LED display according to claim 6, wherein the step of shaking is carried out before galvanizing the wire or at galvanizing the wire.

8. The method for manufacturing an LED display according to claim 5, wherein at least one vacant position is available after removing light-emitting diode chips which fail to generate light, and the method for transferring chips further comprises:
providing at least one preparative light-emitting diode chip; and
placing the at least one preparative light-emitting diode chip into the vacant position, and fixing the at least one preparative light-emitting diode chip on the wire.

9. A method for transferring chips, comprising:
transferring multiple chips onto a target substrate;
respectively providing multiple feed signals to the multiple chips;
moving the multiple chips to trigger at least partial of the multiple chips respectively generate a feedback signal; and
fixing the chips that generate the feedback signals on the target substrate.
